(19) United States
(12) Patent Application Publication
(10) Pub. No.: US 2009/0194322 A1
(43) Pub. Date: Aug. 6, 2009

(54) DEVICE MOUNTING BOARD AND MANUFACTURING METHOD THEREFOR, AND SEMICONDUCTOR MODULE

(76) Inventors: Ryosuke USUI, Ichinomiya-shi (JP); Takeshi Nakamura, Isesaki-shi (JP); Tomohiro Kuzuu, Oota-shi (JP); Yusuke Igarashi, Isesaki-shi (JP)

Correspondence Address: MCDERMOTT WILL & EMERY LLP, 600 13TH STREET, N.W., WASHINGTON, DC, 20005-3096, US

(21) Appl. No.: 12/364,096

(22) Filed: Feb. 2, 2009

(30) Foreign Application Priority Data
Jan. 31, 2008 (JP) 2008-022061
Jan. 22, 2009 (JP) 2009-011616

(51) Int. Cl. H05K 1/16; B05D 3/06; H05K 1/11

(52) U.S. Cl. 174/260; 427/555; 174/262

(57) ABSTRACT

A device mounting board has a double-layer wiring structure where a first wiring layer and a second wiring layer are stacked together with an insulating layer held between the first and second wiring layers. The first wiring layer and the second wiring layer are electrically connected by way of a via conductor provided on a side wall of a through-hole that penetrates the insulating layer. The through-hole that penetrates the insulating layer has a stepped portion. The via conductor, provided along the insulating layer in the via conductor, has a step associated with the stepped portion of the via conductor.

### CROSS-REFERENCE TO RELATED APPLICATIONS

This application is based upon and claims the benefit of priority from the prior Japanese Patent Application No. 2008-022061, filed on Jan. 31, 2008, and Japanese Patent Application No. 2009-011616, filed on Jan. 22, 2009, the entire contents of which are incorporated herein by reference, the entire contents of which are incorporated herein by reference.

### BACKGROUND OF THE INVENTION

1. Field of the Invention

The present invention relates to a device mounting board and a manufacturing method therefor, a semiconductor module and a portable device including the same.

2. Description of the Related Art

Portable electronic devices, such as mobile phones, PDAs, DVCs, and DSCs, are today gaining an increasing variety of functions. And to be accepted by the market, they have to be smaller in size and lighter in weight, and in order to achieve this there is a growing demand for highly-integrated system LSIs. On the other hand, these electronic devices are expected to be easier or handier to use, and therefore the LSIs used in those devices are required to be more functionally sophisticated and better performing. Thus the higher integration of LSI chips is causing increases in I/O count, which in turn generates demand for smaller and thinner packages. To satisfy both these requirements, it is strongly expected that semiconductor packages just right for the high board density packaging of semiconductor parts be developed. In response to such expectations and demands, further thinning is required for a device mounting board which is used to mount semiconductor components thereon.

FIG. 14 is a cross-sectional view of a device mounting board having a conventional double-layer wiring structure. As shown in FIG. 14, a wiring layer 510 and a wiring layer 520 are stacked through the medium of an insulating layer 500 disposed therebetween. A through-hole 530 is provided in the insulating layer 500, and a via conductor 540 is formed along a side wall of the through-hole 530, using a plating method. The wiring layer 510 and the wiring layer 520 are electrically connected to each other by the via conductor 540.

In the conventional device mounting board, the via conductor formed in the through-hole is a thin film having the thickness of about 10 μm, so that there is a problem that the via conductor is liable to be separated or pealed off from the insulating film in the through-hole. In particular, a drill process is done when the through-holes are to be provided in the insulating layer. Thus, the side wall of the through-hole is linear from one face of the device mounting board toward the other face thereof. In this case, when a force or the like is exerted on the device mounting board to make it bent, a displacement in the vertical direction due to a stress caused between the insulating layer and the via conductor is likely to occur in the through-hole, thereby possibly reducing the connection reliability of the device mounting board.

### SUMMARY OF THE INVENTION

The present invention has been made in view of the foregoing circumstances, and a general purpose thereof is to provide a technology for improving the adhesion between a via conductor, which electrically connects stacked wiring layers through an insulating layer, and the insulating layer and for consequently improving the connection reliability in a device mounting board.

One embodiment of the present invention relates to a device mounting board. This device mounting board comprises: an insulating layer; a first wiring layer provided on one face of the insulating layer; a second wiring layer provided on the other face of the insulating layer; a through-hole which penetrates the insulating layer; and a conductor, provided along a side wall of the through-hole, which electrically connects the first wiring layer to the second wiring layer, wherein the through-hole has a stepped portion.

By employing this embodiment, the stepped portion is provided in the through-hole. Thus, the movement of the via conductor at the stepped portion in a substrate stacking direction (in an axial direction of the through-hole) is suppressed. This prevents the via conductor from being displaced and separated from the insulating layer.

In the above-described embodiment, the through-hole may include a first region having an opening at one face side of the insulating layer and a second region, coupled with the first region, having an opening at the other face side thereof, and the first region may be displaced relative to the second region in a surface direction of the insulating layer. In such a case, the diameter of the through-hole in the first region may be equal to the diameter of the through-hole in the second region.

Also, in the above-described embodiment, the through-hole may include a first region having an opening at one face side of the insulating layer and a second region, coupled with the first region, having an opening at the other face side thereof; and when viewed in projection from a direction perpendicular to a face of the insulating layer, at least part of the second region may be located inside the first region. Also, the height of the stepped portion may be smaller than the thickness of the conductor provided along the side wall of the through-hole.

Another embodiment of the present invention relates to a method for manufacturing a device mounting board. This method for manufacturing a device mounting board comprises: preparing an insulating layer where a first metallic layer is provided on one face of the insulation layer and a second metallic layer is provided on the other face thereof; forming a first opening by selectively removing a predetermined region of the first metallic layer; forming a second opening in a manner such that part of a predetermined region of the second metallic layer is selectively removed in a position partially displaced from the predetermined region of the first metallic layer; drilling the insulating layer approximately halfway by irradiating the first opening with laser so as to form a first hole in the insulating layer; drilling the insulating layer approximately halfway by irradiating the second opening with laser so as to form a second hole, coupled with the first hole, in the insulating layer and provide a through-hole in the insulating layer; forming a conductor along a side wall of the through-hole so as to electrically connect the first metallic layer to the second metallic layer; forming a first wiring layer by patterning the first metallic layer; and forming a second wiring layer by patterning the second metallic layer.

By employing this embodiment, the through-hole having a stepped portion inside the insulating layer is formed and therefore the via conductor can be formed along this through-hole. The provision of the stepped portion in the through-hole prevents the via conductor from moving in a substrate stacking direction (in an axial direction of the through-hole) in the stepped portion, thus preventing the via conductor from being displaced and separated from the insulating layer.

In the above-described embodiment, the diameter of the laser irradiated from the second opening may differ from the diameter of the laser irradiated from the first opening.

Still another embodiment of the present invention relates to a semiconductor module. This semiconductor module comprises: a device mounting board according to any of the above-described embodiments; and a semiconductor device mounted on the device mounting board.

According to this embodiment, the connection reliability of the semiconductor module can be improved.

Still another embodiment of the present invention relates to a mobile apparatus. This mobile apparatus mounts a semiconductor module according to any of the above-described embodiments.

According to this embodiment, the connection reliability of the mobile apparatus can be improved.

It is to be noted that any arbitrary combinations or rearrangement of the aforementioned structural components and so forth are all effective as and encompassed by the embodiments of the present invention.

Moreover, this summary of the invention does not necessarily describe all necessary features so that the invention may also be sub-combination of these described features.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view showing a structure of a semiconductor module according to a first embodiment of the present invention;

FIGS. 2A to 2E are cross-sectional views showing a process in a method for manufacturing a device mounting board according to a first embodiment of the present invention;

FIGS. 3A to 3C are cross-sectional views showing a process in a method for manufacturing a device mounting board according to a first embodiment of the present invention;

FIGS. 4A and 4B are cross-sectional views showing a process in a method for manufacturing a device mounting board according to a first embodiment of the present invention;

FIG. 5 is a cross-sectional view showing a structure of a semiconductor module according to a second embodiment of the present invention;

FIG. 6 is a cross-sectional view showing a structure of a semiconductor module according to a third embodiment of the present invention;

FIG. 7 is a cross-sectional view showing a structure of a semiconductor module according to a fourth embodiment of the present invention;

FIG. 8 is a cross-sectional view showing a structure of a semiconductor module according to a fifth embodiment of the present invention;

FIG. 9 illustrates a structure of a mobile phone provided with a semiconductor module according to each embodiment of the present invention;

FIG. 10 is a partial cross-sectional view (cross-sectional view of a first casing) of a mobile phone shown in FIG. 9;

FIG. 11 is a cross-sectional view of openings when through-holes are formed in a device mounting board according to a modification;

FIG. 12 is a cross-sectional view showing a structure of a semiconductor module according to a modification;

FIG. 13 is a cross-sectional view showing a structure of a semiconductor module according another modification; and

FIG. 14 is a cross-sectional view of a device mounting board having a conventional double-layer wiring structure.

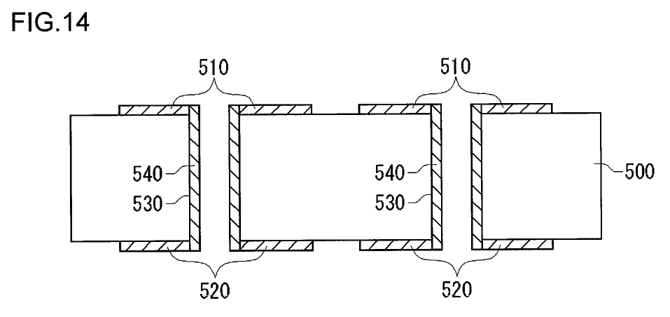

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings. Note that in all of the Figures the same reference numerals are given to the same components and the description thereof is omitted as appropriate.

### First Embodiment

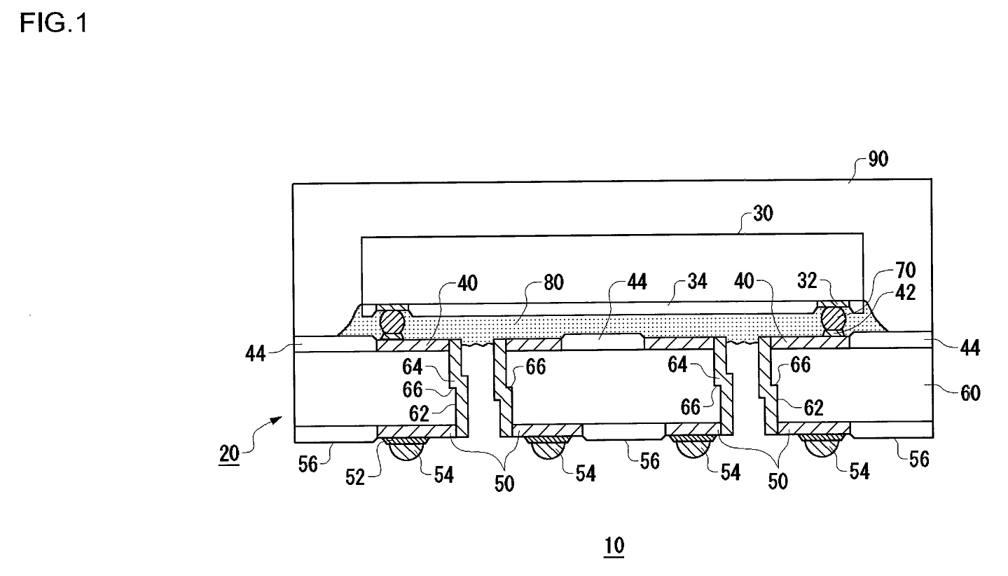

FIG. 1 is a cross-sectional view showing a structure of a semiconductor module 10 according to a first embodiment of the present invention. The semiconductor module 10 has a packaged structure where a semiconductor device 30 is mounted on a device mounting board 20.

The device mounting board 20 has a double-layer wiring structure where a first wiring layer 40 and a second wiring layer 50 are stacked through the medium of an insulating layer 60 held therebetween. The first wiring 40 and the second wiring layer 50 are each formed of metal with satisfactory electric conductivity. The device mounting board 20, which does not have a supporting substrate, is of thin type and can achieve high-density packaging of semiconductor devices and the like. Such a structure is achieved by Integrated System in Board or ISB (registered trademark) developed by the applicant of this patent specification. The detailed description thereof is given in Japanese Patent Application Laid-Open No. 2002-110717, for instance.

The insulating layer 60 is a material where insulating resin is impregnated with glass cloth. The material preferably used for the resin is, for instance, an organic type resin, such as epoxy resin, a melamine derivative (e.g., BT resin), liquid-crystal polymer, PPE resin, polyimide resin, fluorine resin, phenol resin, or polyamide bismaleimide. The thickness of the insulating layer 60 may be 110 μm, for instance.

The first wiring layer 40 and the second wiring layer 50 are electrically connected to each other by way of a via conductor 64 provided on a side wall of a through-hole 62 that penetrates the insulating layer 60. The diameter of the through-hole 62 is 75 μm, for instance. The via conductor 64 is formed by a metal, with satisfactory electric conductivity, such as copper. The thickness of the via conductor 64 is 10 μm, for instance.

A stepped portion 66 is provided in the through-hole 62 that penetrates the insulating layer 60. Since the via conductor 64 is provided along the insulating layer 60 within the through-hole 62, the via conductor 64 also has a step corresponding to said stepped portion 66. The provision of the stepped portion 66 in the through-hole 62 prevents the via conductor 64 from moving in a substrate stacking direction (in an axial direction of the through-hole 62) in the stepped portion 66, thus preventing the via conductor 64 from being displaced and separated from the insulating layer 60. In other words, the stepped portion 66 provided in the through-hole 62 functions as a stopper that suppresses and prevents the via conductor 66 from being displaced in the substrate stacking direction.

It is preferable that the height of the stepped portion 66 is smaller than the film thickness of the via conductor 64. If so, the via conductor 64 will be likely to follow the shape of the insulating layer in the stepped portion 66 and therefore the continuity of the via conductor 60 can be enhanced. In particular, the stepped portion 66 can be sufficiently covered by forming the via conductor 64 by an electroless plating method and an electrolytic plating method and therefore this stepped portion 66 can prevent the occurrence of disconnection in the via conductor 64.

On an underside of the device mounting board 20, a plurality of electrode pads 52 are provided in an array in predetermined positions of the second wiring layer 50. A solder ball 54 is bonded to each electrode pad 52. A heat-resisting solder resist layer 56 is provided in a gap area of the electrode pad 52. The solder resist layer 56 protects the insulating layer 60 against any damage that may be caused by the heat during a solder bonding process.

On an upper-face side of the device mounting board 20, a plurality of electrode pads 42 are provided in predetermined positions of the first wiring layer 40. The electrode pad 42 is used for flip-chip connection between the semiconductor device 30 and the device mounting board 20. A heat-resisting solder resist layer 44 is provided in a gap area of the electrode pad 42. The solder resist layer 44 protects the insulating layer 60 against any damage that may be caused by the heat during a solder bonding process.

The semiconductor device 30 is an active element such as an integrated circuit (IC) and a large-scale integrated circuit (LSI). The semiconductor device 30 is flip-chip connected to the upper surface of the device mounting board 20 in such a manner that a surface of the semiconductor device 30 on which the electrode pad 32 is formed is positioned downward. More specifically, the electrode pad 32 provided on the semiconductor pad 30 is connected to the electrode pad 42 provided on the device mounting board 20 by way of a solder ball 70. A space between adjacent electrode pads 32 are protected by a protective layer 34 made of resin such as polyimide. An underfill material 80 is filled in between the semiconductor device 30 and the device mounting board 20. The underfill material 80 protects a joint between the electrode pad 42 and the solder ball 70. The semiconductor device 30 is sealed by a molded resin 90 and may be packaged thereby.

(Manufacturing Method)

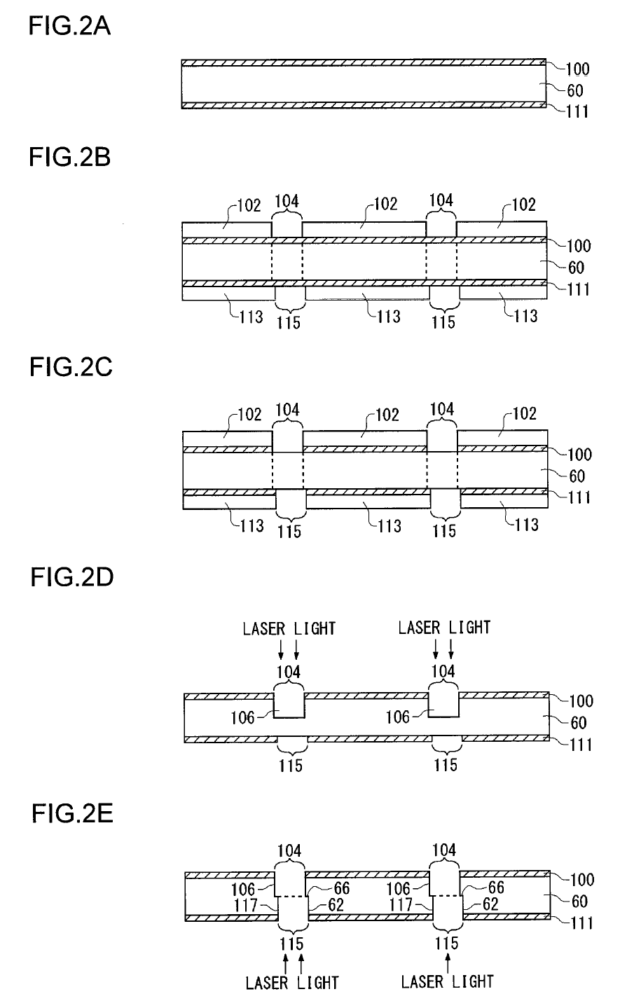

A method for manufacturing a device mounting board 20 according to the first embodiment will be described referring to FIG. 2A to FIG. 4B.

As shown in FIG. 2A, an insulating layer 60 is prepared where a first metallic layer 100 made of copper foil is provided on one face of the insulating layer 60 and a second metallic layer 111 made of copper foil is provided on the other face thereof.

Then, as shown in FIG. 2B, a resist 102 and a resist 113 are patterned respectively on the first metallic layer 100 and the second metallic layer 111 by using a photolithography method. The resist 102 is formed so that the first metallic layer 100 is partially exposed in a first opening 104. The resist 113 is formed so that the second metallic layer 111 is partially exposed in a second opening 115. It is to be noted here that the first opening 104 is formed in a such a manner that the first opening 104 is displaced in a surface direction (horizontal direction in FIG. 2B) of the insulating layer 60 by 3 to 5 μm, for example. The size of the first opening 104 and the second opening 115 is each 75 μmφ, for example.

Then, as shown in FIG. 2C, the first metallic layer 100 in the first opening 104 and the second metallic layer 111 in the second opening 115 are removed by a wet etching technique using a ferric chloride solution.

Then, as shown in FIG. 2D, after the removal of the resist 102 and the resist 113, the first opening 104 is irradiated with CO₂ laser (the pulse width 10 μsec and the pulse interval of 3 shots, for example) and drilled halfway through the insulating layer 60 so as to form a first hole 106. The diameter of laser irradiated to the first opening 104 is 100 μm, for example.

Then, as shown FIG. 2E, the second opening 115 is irradiated with CO₂ laser (the pulse width 10 μsec and the pulse interval of 3 shots, for example) and drilled halfway through the insulating layer 60 so as to form a second hole 117. The diameter of laser irradiated to the second opening 115 is 100 μm, for example. The second opening 115 is drilled until the second hole 117 is finally coupled with the first hole 106. As a result, a through-hole 62 is formed in the insulating layer 60. Since the first opening 104 irradiated with CO₂ laser is displaced relative to the second opening 115 in the surface direction of the insulating layer 60, a stepped portion 66 is formed in the through-hole 62. A “first region” in the through-hole as claimed may encompass a first hole 106, whereas a “second region” in the through-hole as claimed may encompass a second hole 117.

When the first opening 104 and the second opening 115 is irradiated with CO₂ laser, the light source of CO₂ laser may be fixed and the surface of the insulating layer 60 disposed counter to the light source of laser may be interchanged.

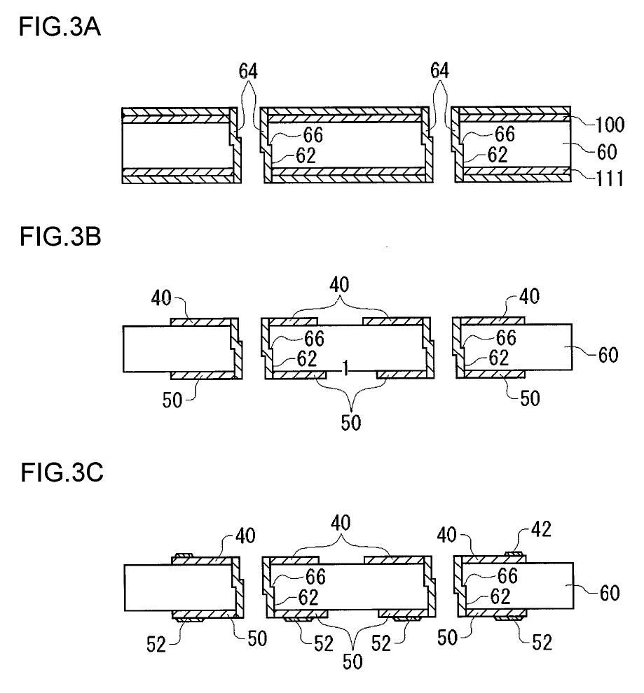

Then, as shown in FIG. 3A, a via conductor 64 made of copper is formed on the side surface of the through-hole 62 using an electroless plating method and an electrolytic plating method. The film thickness of the via conductor 64 is 10 μm, for example. Since the stepped portion 66 is provided in the through-hole 62, a step corresponding to this stepped portion 66 is also caused in the via conductor 64 provided along the insulating layer 60. Also, the film thickness of the first metallic layer 100 and the second metallic layer 111 is increased by the plating process.

Then, as shown in FIG. 3B, a first wiring layer 40 and a second wiring layer 50 are formed by patterning the first metallic layer 100 and the second metallic layer 111, respectively.

Then, as shown in FIG. 3C, an electrode pad 42 is formed in a predetermined position of the first wiring layer 40. An electrode pad 52 is formed in a predetermined position of the second wiring layer 50. The electrode pad 42 and the electrode pad 52 can be formed by forming a film of a Ni/Au layer thereon using a plating method.

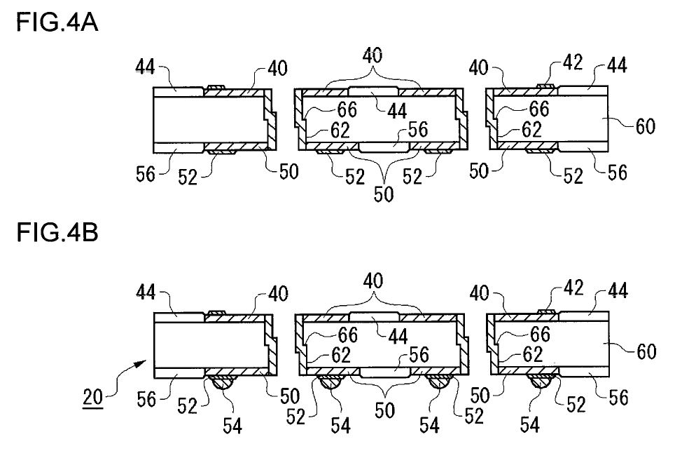

Then, as shown in FIG. 4A, a solder resist layer 44 and a solder resist layer 56 are formed on a surface of the insulating layer 60 in a gap of the first wiring layer 40 and a surface of the insulating layer 60 in a gap in the second wiring layer 50, respectively.

Then, as shown in FIG. 4B, solder balls 54 for use with external connection are mounted on the electrode pads 52.

The device mounting board 20 according to the first embodiment is thus manufactured through the processes as described above.

### Second Embodiment

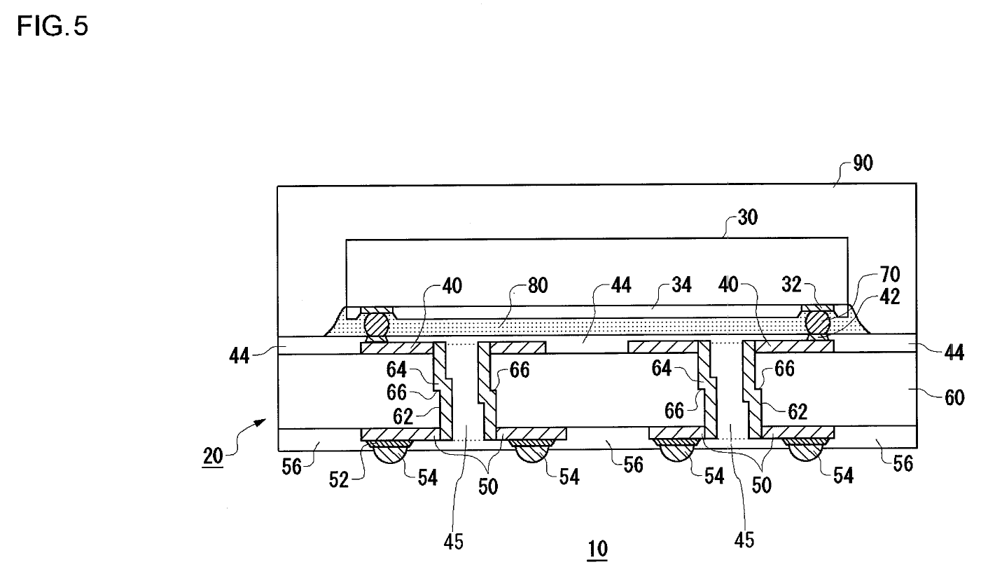

FIG. 5 is a cross-sectional view showing a structure of a semiconductor module 10 according to a second embodiment of the present invention. Similar to the first embodiment, the semiconductor module 10 according to the second embodiment has a packaged structure where a semiconductor device 30 is mounted on a device mounting board 20. The same components as those of the first embodiment are given the same reference numerals and the explanation thereof is omitted as appropriate, and a description will be given here of the semiconductor module 10 according to the second embodiment centering around a structure different from that of the first embodiment.

In the semiconductor module 10 according to the second embodiment, a solder resist layer 44 is formed over the entire surface of a device mounting board 20 except for the mounting region of solder balls 70. In other words, the solder balls 70 are mounted on electrode pads 42 in openings of the solder resist layer 44 formed over the whole upper surface of the device mounting board 20. Similarly, a solder resist layer 56 is formed over the entire underside of the device mounting board 20 except for the mounting region of solder balls 54. A solder resist layer 45 is embedded into the through-hole 62.

The basic method for manufacturing the device mounting board 20 used for the semiconductor module 10 according to the second embodiment is the same as that of the first embodiment (FIG. 2 to FIG. 4). In the second embodiment, after the process shown in FIG. 3C, the solder resist layer 45 is embedded into the through-hole 62, and the solder resist layer 44 and the solder resist layer 56 are formed on the whole top surface of the insulating layer 60 at the first wiring layer 40 side and the whole bottom surface of the insulating layer 60 at the second wiring layer 50 side, respectively. After this, a portion to remain is hardened by subjecting it to exposure using a resist mask and then openings corresponding to the electrode pad 42 and the electrode pad 52 are formed in the solder resist layer 44 and the solder resist 56, respectively, by removing an unwanted part. The processes after this are the same as those from FIG. 4B onward as explained in the first embodiment.

According to the second embodiment, the through-hole 62 filled with the solder resist layer 45 can prevent external moisture from entering the semiconductor module 10.

Also, because of the through-hole 62 filled with the solder resist layer 45, the motion of the via conductor 64 is suppressed by the solder resist layer 45. This prevents the via conductor 64 from being disconnected due to heat contraction.

With such advantageous effects as described above, the connection reliability of the semiconductor module 10 can be further enhanced.

### Third Embodiment

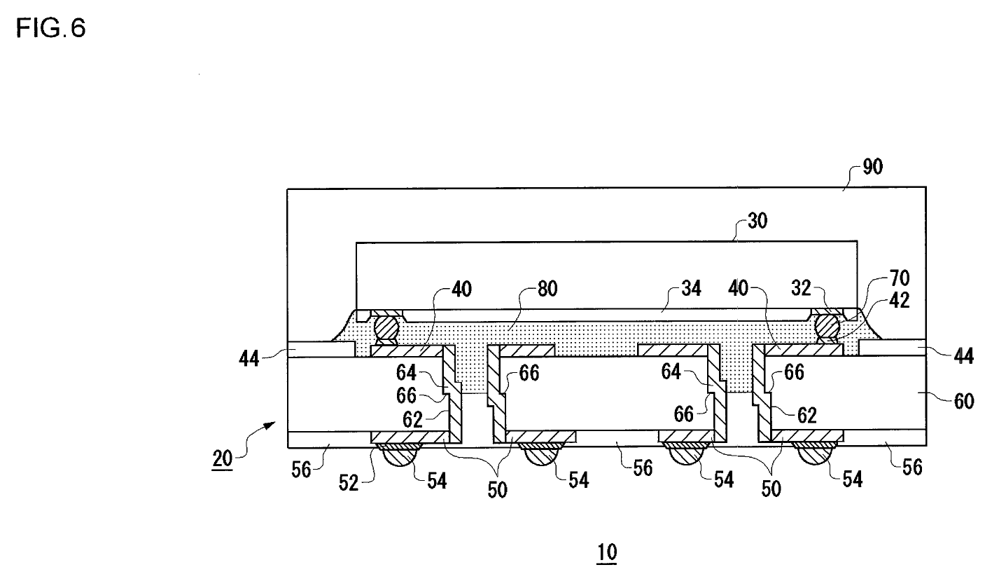

FIG. 6 is a cross-sectional view showing a structure of a semiconductor module 10 according to a third embodiment of the present invention. Similar to the first embodiment, the semiconductor module 10 according to the third embodiment has a packaged structure where a semiconductor device 30 is mounted on a device mounting board 20. The same components as those of the first embodiment are given the same reference numerals and the explanation thereof is omitted as appropriate, and a description will be given here of the semiconductor module 10 according to the third embodiment centering around a structure different from that of the first embodiment.

In the semiconductor module 10 according to the third embodiment, a solder resist layer 44 is formed over the entire upper surface of a device mounting board 20 except for the underneath of the mounting region of the semiconductor device 30 and the mounting region of solder balls 70. In the underneath of the semiconductor device 30, an underfill material 80 is filled in between an insulating layer 60 and a first wiring layer 40. Further, the underfill material 80 is filled halfway in a through-hole 62 from an opening at a first wiring layer 40 side of the through-hole 62 (i.e., staring from the opening at the first wiring layer 40 side of the through-hole 62 to a central part thereof in a hole direction).

A solder resist layer 56 is formed over the entire underside of the device mounting board 20 except for the mounting region of solder balls 54. The solder resist layer 56 is filled halfway in the through-hole 62 from an opening at a second wiring layer 50 side of the through-hole 62 (i e., staring from the opening at the second wiring layer 50 side of the through-hole 62 to the central part thereof in the hole direction).

The basic method for manufacturing the device mounting board 20 used for the semiconductor module 10 according to the embodiment is the same as that of the first embodiment (FIG. 2 to FIG. 4). In the third embodiment, after the process shown in FIG. 3C, the solder resist layer 45 is embedded into the through-hole 62, and the solder resist layer 44 and the solder resist layer 56 are formed on the whole top surface of the insulating layer 60 at the first wiring layer 40 side and the whole bottom surface of the insulating layer 60 at the second wiring layer 50 side, respectively. After this, a portion to remain is hardened by subjecting it to exposure using a resist mask, and the solder resist layer 44 is formed over the entire upper surface of the device mounting board 20, except for the underneath of the mounting region of the semiconductor device 30 and the mounting region of solder balls 70, by removing an unwanted part. At this time, the through-hole 62 is hollowed out approximately halfway from the opening at the first wiring layer 40 side. At the same time, openings corresponding to the electrode pads 52 are formed in the solder resist 56 which is formed on the surface of the insulating layer 60 at the second wiring layer 50 side. A solder resist layer remains halfway from the opening of the through-hole 62 at the second wiring layer 50 side so as to become a part of the solder resist layer 56. The processes after this are the same as those from FIG. 4B onward as explained in the first embodiment. When the underfill material 80 is filled in between the device mounting board 20 and the semiconductor device 30 after the semiconductor device 30 has been mounted on the device mounting board 20, the underfill material 80 is also filled in a hollow portion formed halfway from the opening of the through-hole 62 at the first wiring layer 40 side.

According to the third embodiment, the through-hole 62 filled with the underfill material 80 and the solder resist layer 56 can prevent external moisture from entering the semiconductor module 10.

Also, because of the through-hole 62 filled with the underfill material 80 and the solder resist layer 56, the motion of the via conductor 64 is suppressed by the solder resist layer 45. This prevents the via conductor 64 from being disconnected due to heat contraction.

With such advantageous effects as described above, the connection reliability of the semiconductor module 10 can be further enhanced.

In this third embodiment, the solder resist layer 44 is not formed on the upper surface of the device mounting board 20 which corresponds to the underneath of the mounting region of the semiconductor device 30. Hence, the interference between the solder balls 70 and the solder resist layer 44 in the mounting region of the semiconductor device 30 is suppressed. As a result, the size of the solder ball 70 can be made smaller, and the gap between the device mounting board 20 and the semiconductor device 30 can be made smaller. In other words, the height of the semiconductor module 10 can be reduced.

### Fourth Embodiment

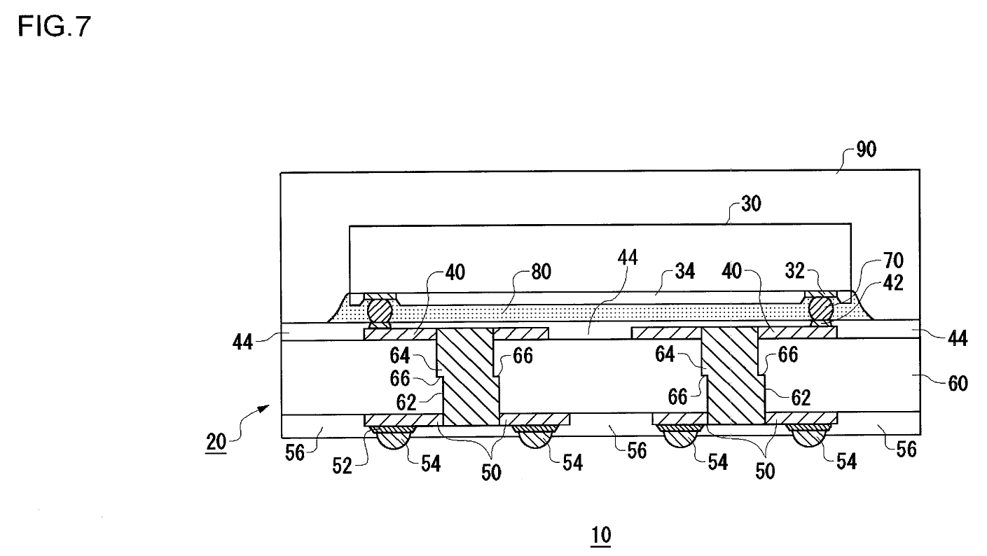

FIG. 7 is a cross-sectional view showing a structure of a semiconductor module 10 according to a fourth embodiment of the present invention. Similar to the first embodiment, the semiconductor module 10 according to the fourth embodiment has a packaged structure where a semiconductor device 30 is mounted on a device mounting board 20. The same components as those of the first embodiment are given the same reference numerals and the explanation thereof is omitted as appropriate, and a description will be given here of the semiconductor module 10 according to the fourth embodiment centering around a structure different from that of the first embodiment.

In the semiconductor module 10 according to the fourth embodiment, a solder resist layer 44 is formed over the entire upper surface of a device mounting board 20 except for the mounting region of solder balls 70. In other words, the solder balls 70 are mounted on electrode pads 42 in openings of the solder resist layer 44 formed over the whole upper surface of the device mounting board 20. Similarly, a solder resist layer 56 is formed over the entire underside of the device mounting board 20. A via conductor 64 is embedded into the through-hole 62.

The basic method for manufacturing the device mounting board 20 used for the semiconductor module 10 according to the fourth embodiment is the same as that of the first embodiment (FIG. 2 to FIG. 4). In the fourth embodiment, after the through-hole 62 in is completely embedded with the via conductor 64, plating films formed on both the main surfaces of the insulating layer 60 are turned into thin films. After this and through the processes shown in FIG. 3B and FIG. 3C, the solder resist layer 44 and the solder resist layer 56 are formed on the whole top surface of the insulating layer 60 at the first wiring layer 40 side and the whole bottom surface of the insulating layer 60 at the second wiring layer 50 side, respectively. After this, a portion to remain is hardened by subjecting it to exposure using a resist mask and then openings corresponding to the electrode pad 42 and the electrode pad 52 are formed in the solder resist layer 44 and the solder resist 56, respectively, by removing an unwanted part. The processes after this are the same as those from FIG. 4B onward as explained in the first embodiment.

By employing the fourth embodiment, the via conductor 64 is formed to fill the through-hole 62 in its entirety, so that the resistance of the via conductor 64 can be reduced and therefore the electric characteristics of the semiconductor module 10 can be improved.

Also, a stepped portion 66 is provided in the through-hole 62 filled with the via conductor 62. Hence, the stress occurs in this stepped portion 66 in a dispersed manner. As a result, the provision of the stepped portions 66 suppresses the stress concentrated in edges or corners of the via conductor 62 at the first wiring layer 40 side and edges or corners of the via conductor 62 at the second wiring layer 50 side. In consequence, there will be less likelihood of separation of and cracking in the via conductor 62, which in turn will improve the reliability of the semiconductor module 100.

### Fifth Embodiment

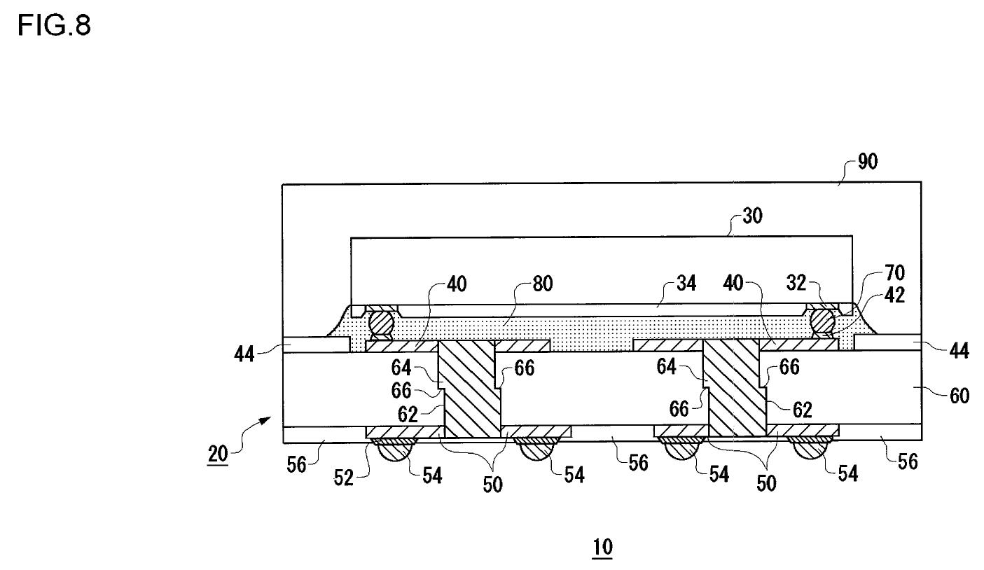

FIG. 8 is a cross-sectional view showing a structure of a semiconductor module 10 according to a fifth embodiment of the present invention. The semiconductor module 10 is a modification of the semiconductor module 10 according to the fourth embodiment. The same components as those of the fourth embodiment are given the same reference numerals and the explanation thereof is omitted as appropriate, and a description will be given here of the semiconductor module 10 according to the modification centering around a structure different from that of the first embodiment.

Similarly to the third embodiment, in the semiconductor module 10 according to this fifth embodiment, a solder resist layer 44 is formed over the entire upper surface of a device mounting board 20 except for the underneath of the mounting region of the semiconductor device 30 and the mounting region of solder balls 70. In the underneath of the semiconductor device 30, an underfill material 80 is filled in between an insulating layer 60 and a first wiring layer 40. Similarly to the fourth embodiment, a via conductor 64 is filled in a through-hole 62.

By employing the fifth embodiment, the via conductor 64 is formed to fill the through-hole 62 in its entirety, so that the resistance of the via conductor 64 can be reduced and therefore the electric characteristics of the semiconductor module 10 can be improved.

Also, a stepped portion 66 is provided in the through-hole 62 filled with the via conductor 62. Hence, the stress occurs in this stepped portion 66 in a dispersed manner. As a result, the provision of the stepped portions 66 suppresses the stress concentrated in edges or corners of the via conductor 62 at the first wiring layer 40 side and edges or corners of the via conductor 62 at the second wiring layer 50 side. In consequence, the occurrence of separation of and cracking in the via conductor 62 is suppressed, thereby improving the reliability of the semiconductor module 100.

In this fifth embodiment, the solder resist layer 44 is not formed on the upper surface of the device mounting board 20 which corresponds to the underneath of the mounting region of the semiconductor device 30. Hence, the interference between the solder balls 70 and the solder resist layer 44 in the mounting region of the semiconductor device 30 is suppressed. As a result, the size of the solder ball 70 can be made smaller, and the gap between the device mounting board 20 and the semiconductor device 30 can be made smaller. In other words, the height of the semiconductor module 10 can be reduced.

Next, a description will be given of a mobile apparatus (portable device) provided with a semiconductor module according to the above described embodiments. The mobile apparatus presented as an example herein is a mobile phone, but it may be any electronic apparatus, such as a personal digital assistant (PDA), a digital video cameras (DVC) or a digital still camera (DSC).

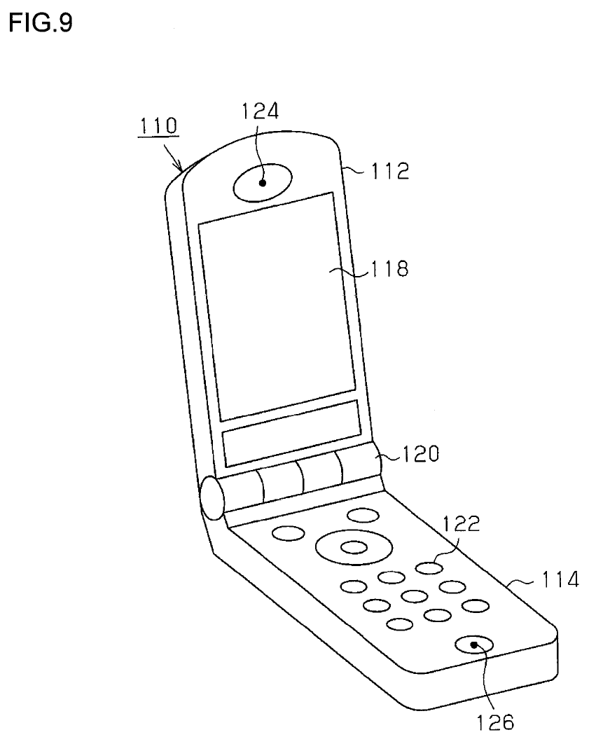

FIG. 9 illustrates a structure of a mobile phone provided with a semiconductor module 30 according to the preferred embodiments of the present invention. A mobile phone 111 has a structure of a first casing 112 and a second casing 114 jointed together by a movable part 120. The first casing 112 and the second casing 114 are turnable/rotatable around the movable part 120 as the axis. The first casing 112 is provided with a display unit 118 for displaying characters, images and other information and a speaker unit 124. The second casing 114 is provided with a control module 122 with operation buttons and a microphone 126. Note that the semiconductor module 30 according to the above embodiment of the present invention is mounted within a mobile phone 111 such as this. The semiconductor module, according to each embodiment, mounted on a mobile phone may be used for a power supply circuit used to drive each circuit, an RF generation circuit for generating RF, a digital-to-analog converter (DAC), an encoder circuit, a driver circuit for a backlight used as the light source of a liquid-crystal panel used for a display of the mobile phone, and the like.

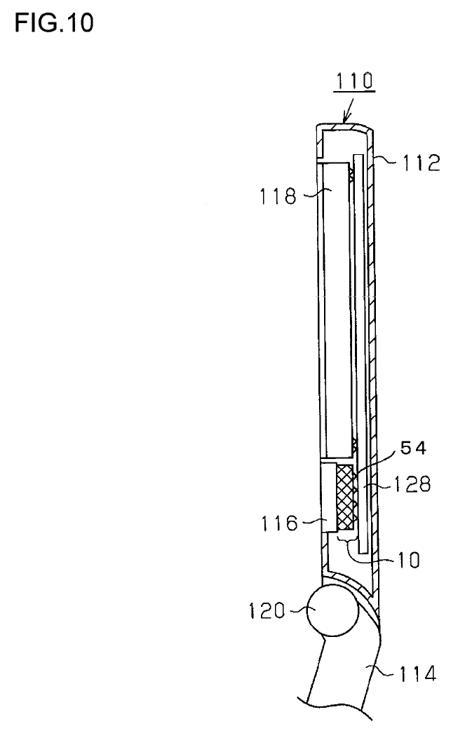

FIG. 10 is a partially schematic cross-sectional view (cross-sectional view of a first casing 112) of the mobile phone shown in FIG. 9. The semiconductor module 10 according to each of the above-described embodiments is mounted on a printed circuit board 128 via the external connection electrodes (solder bumps) 54 and is coupled electrically to the display unit 118 and the like by way of the printed circuit board 128. Also, a radiating substrate 116, which may be a metallic substrate, is provided on the back side of the semiconductor module 10 (opposite side of external connection electrodes 54), so that the heat generated from the semiconductor module 10, for example, can be efficiently released outside the first casing 112 without getting trapped therein.

According to the mobile apparatus provided with a semiconductor module according to any of the above-described embodiments, the following advantageous effects can be achieved.

In the device mounting board that constitutes the semiconductor module 10, the separation of the via conductor, provided to connect one wiring layer with another, from the insulating layer is prevented. As a result, the reliability of the semiconductor module 10 is improved and therefore the reliability of the mobile apparatus that mounts such the semiconductor module 10 is improved.

The heat generated from the semiconductor module 10 can be efficiently released to the outside by way of the radiating substrate 116. Thus, the rise in temperature of the semiconductor module 10 is suppressed and the thermal stress between a rewiring pattern and an insulating layer is reduced. Accordingly, as compared with a case without the radiating substrate 116, the connection reliability (heat resistance reliability) between the electrodes and projected portions (bumps) is improved. Or, the separation of the rewiring pattern inside the semiconductor module from the insulating layer is prevented and therefore the reliability (heat resistance reliability) of the semiconductor module 10 is improved. As a result, the reliability (heat resistance reliability) of the mobile apparatus can be improved.

By the use of the device mounting board manufactured by a manufacturing process as described in the above embodiments, the semiconductor module 10 is thinner and smaller, so that the mobile device incorporating such the semiconductor module 10 can be made thinner and smaller.

As described above, in the conventional practice the through-hole 530 is provided in the insulating layer 500 of the device mounting board by a drill process. In this case, the opening in the upper face of the though-hole may be displaced greatly from the opening in the lower face thereof by several tens of μm if the insulating resin layer is more rigid or substrates each including an insulating layer and wiring layers at the both surfaces are overlapped in layers and then the device mounting board is drilled from one of the faces so as to form the through-hole. For this reason, a margin must be taken into account and set which predicts the “displacement” beforehand. Hence, it is difficult to achieve a thinner and smaller device mounting board and a semiconductor module or mobile apparatus incorporating such a thinner and smaller device mounting board.

When the stepped portion of several μm is provided as in the present embodiments, the size of the device mounting board increases by the size of the stepped portion only. Hence, the device mounting board can be made thinner and smaller and therefore the semiconductor module or mobile apparatus incorporating such the device mounting board can be also made thinner and smaller. Since the device mounting board is drilled from the both faces so as to the through-hole, the amount of “displacement” is larger than the size of the stepped portion as compared with a case where it is drilled from one face only. As a result, with the structure according to the present embodiments, the device mounting board can be made thinner and smaller and therefore the semiconductor module or mobile apparatus incorporating such the device mounting board can be also made thinner and smaller

The present invention is not limited to the above-described embodiments only, and it is understood by those skilled in the art that various modifications such as changes in design may be made based on their knowledge and the embodiments added with such modifications are also within the scope of the present invention.

In the above-described embodiments, to form the through-hole 62 having the stepped portion 66 in the insulating layer 60, the first opening 104 and the second opening 115 are irradiated, in this order, with laser using one CO₂ laser (see FIG. 2D and FIG. 2E). For example, the first opening 104 and the second opening 115 may be irradiated simultaneously with laser using two CO₂ so as to form the through-hole 62.

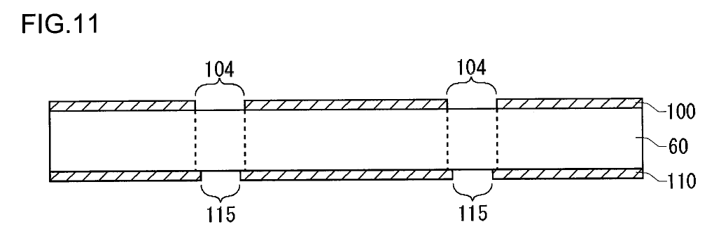

In the above-described embodiments, the diameter of the first opening 104 and the diameter of the second opening 115 are set equal to each other. And the stepped portion 66 is formed in such a manner that the position where the first opening 104 is shifted relative to the second opening 115 in the surface direction. However, the method for forming the stepped portion 66 is not limited thereto and, for example, as shown in FIG. 11, the diameter of the first opening 104 is made larger than the diameter of the second opening 115, so that the second opening 115 is placed within the region of the first opening 104 when viewed from the substrate stacking direction. The insulating layer 60 is drilled halfway therethrough by irradiating the CO₂ laser to the first opening 104. Then, the through-hole 62 is formed by irradiating the CO₂ laser to the second opening 115, so as to form the stepped portion in the through-hole 62.

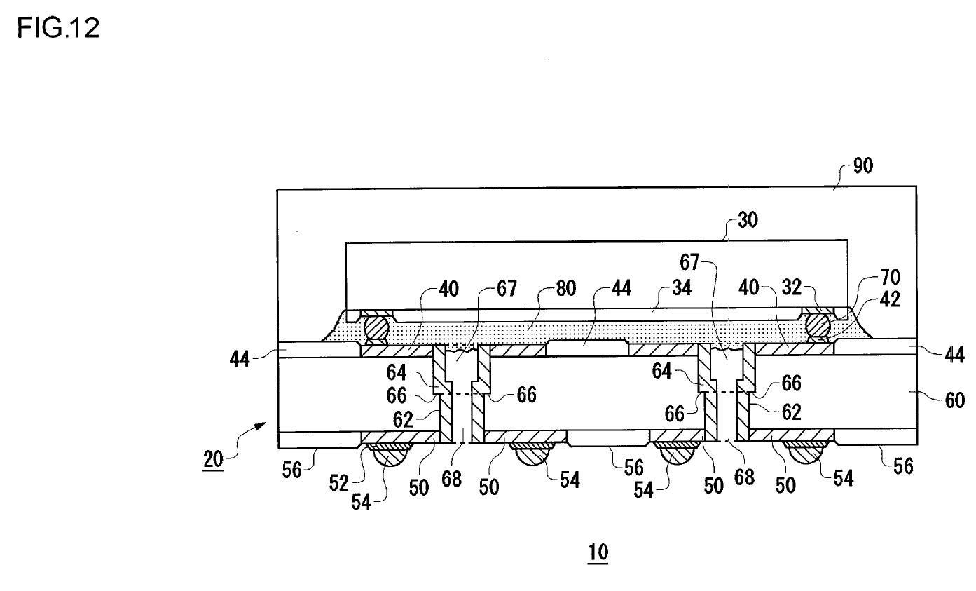

FIG. 12 is a cross-sectional view showing a structure of a semiconductor module manufactured through the process for forming the stepped portion shown in FIG. 11. In this modification, the through-hole 62 includes a first region 67 and a second region 68. The first region 67 has an opening at one face side (upper side in FIG. 12) of the insulating layer 60. The second region 68 has an opening at the other face side (lower side in FIG. 12) of the insulating layer 60, and is coupled with the first region 67. As shown in FIG. 12, the diameter of the through-hole 62 in the first region 67 is larger than that in the second region 68. As a result, when viewed in projection from a direction perpendicular to a face of the insulating layer 60 (namely, from the above in FIG. 12), the second region 68 is located on the inward side of the first region 67. This structure according to the present modification can also achieve the same advantageous effects as with the above-described embodiments. It suffices if the through-hole 62 has a stepped portion. Accordingly, when viewed in projection from the direction perpendicular to the face of the insulating layer 60, a part of the second region 68 may be positioned on the inward side of the first region 67.

In particular, if the whole second region 68 is positioned on the inward side of the first region 67, the diameter of the through-hole in a position where the stepped portion 66 is formed will be equal to the diameter of the through-hole in the second region 68. That is, the stepped portion 66 can be formed without the formation of an area where the diameter of the through-hole is partially narrower. This allows the aspect ratio of the through-hole to remain smaller and also allows the formation of the continuous via conductor 64 of high reliability.

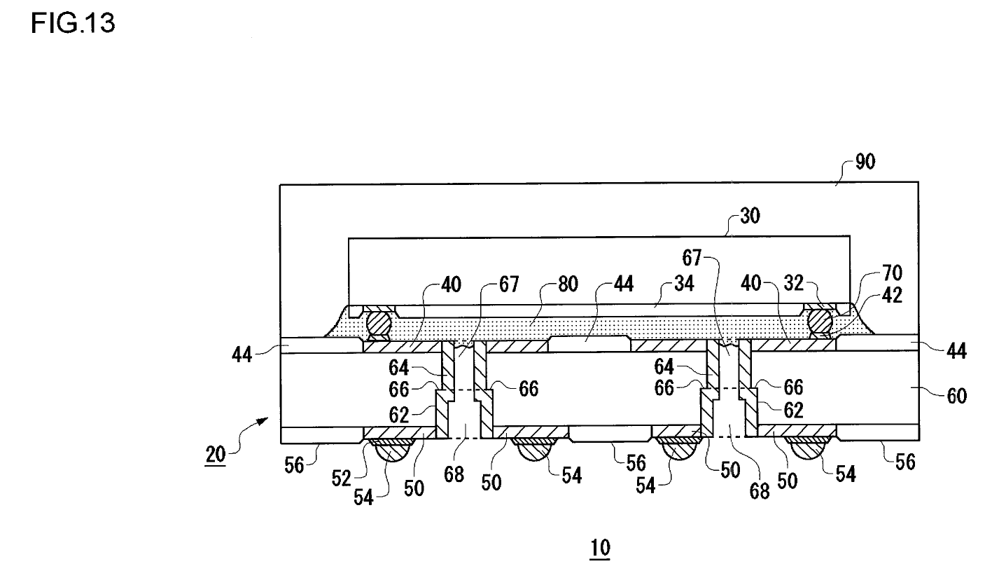

FIG. 13 is a cross-sectional view showing a structure of a semiconductor module according another modification. In this modification, the diameter of the through-hole 62 in the first region 67 is smaller than that in the first region 67. As a result, when viewed in projection from a direction perpendicular to the face of the insulating layer 60 (namely, from the below in FIG. 12), the first region 67 is positioned on the inward side of the second region 68. This structure according to the present modification can also achieve the same advantageous effects as with the above-described embodiments.

While the preferred embodiments of the present invention and their modifications have been described using specific terms, such description is for illustrative purposes only, and it is to be understood that changes and variations may further be made without departing from the spirit or scope of the appended claims.

What is claimed is:

1. A device mounting board, comprising:
an insulating layer;
a first wiring layer provided on one face of said insulating layer;
a second wiring layer provided on the other face of said insulating layer;
a through-hole which penetrates said insulating layer; and
a conductor, provided along a side wall of said through-hole, which electrically connects said first wiring layer to said second wiring layer,
wherein said through-hole has a stepped portion.

2. A device mounting board according to claim 1, wherein said through-hole includes a first region having an opening at one face side of said insulating layer and a second region, coupled with the first region, having an opening at the other face side thereof, and
wherein the first region is displaced relative to the second region in a surface direction of said insulating layer.

3. A device mounting board according to claim 1, wherein the diameter of said through-hole in the first region is equal to the diameter of said through-hole in the second region.

4. A device mounting board according to claim 1, wherein said through-hole includes a first region having an opening at one face side of said insulating layer and a second region, coupled with the first region, having an opening at the other face side thereof, and
wherein when viewed in projection from a direction perpendicular to a face of said insulating layer, at least part of the second region is located inside the first region.

5. A device mounting board according to claim 1, wherein the height of the stepped portion is smaller than the thickness of said conductor provided along the side wall of said through-hole.

6. A device mounting board according to claim 2, wherein the height of the stepped portion is smaller than the thickness of said conductor provided along the side wall of said through-hole.

7. A device mounting board according to claim 3, wherein the height of the stepped portion is smaller than the thickness of said conductor provided along the side wall of said through-hole.

8. A device mounting board according to claim 4, wherein the height of the stepped portion is smaller than the thickness of said conductor provided along the side wall of said through-hole.

9. A method for manufacturing a device mounting board, the method comprising:
preparing an insulating layer where a first metallic layer is provided on one face of the insulation layer and a second metallic layer is provided on the other face thereof;
forming a first opening by selectively removing a predetermined region of the first metallic layer;
forming a second opening in a manner such that part of a predetermined region of the second metallic layer is selectively removed in a position partially displaced from the predetermined region of the first metallic layer;
drilling the insulating layer approximately halfway by irradiating the first opening with laser so as to form a first hole in the insulating layer;
drilling the insulating layer approximately halfway by irradiating the second opening with laser so as to form a second hole, coupled with the first hole, in the insulating layer and provide a through-hole in the insulating layer;
forming a conductor along a side wall of the through-hole so as to electrically connect the first metallic layer to the second metallic layer;
forming a first wiring layer by patterning the first metallic layer; and
forming a second wiring layer by patterning the second metallic layer.

10. A method, for manufacturing a device mounting board, according to claim 9, wherein the diameter of the laser irradiated from the second opening differs from the diameter of the laser irradiated from the first opening.

11. A semiconductor module, comprising:
a device mounting board according to claim 1; and
a semiconductor device mounted on said device mounting board.
